(19) United States
(12) Patent Application Publication
(10) Pub. No.: US 2008/0309363 A1
(43) Pub. Date: Dec. 18, 2008

(54) PROBE ASSEMBLY WITH WIRE PROBES

(75) Inventors: BYUNG-HEE JEON, Seongnam-si (KR); DAE-CHEOL KANG, Namyangju-si (KR)

Correspondence Address: KNOBBE MARTENS OLSON & BEAR LLP, 2040 MAIN STREET, FOURTEENTH FLOOR, IRVINE, CA, 92614, US

(73) Assignee: NICTECH CO., LTD., SEOUL (KR)

(21) Appl. No.: 12/139,372

(22) Filed: Jun. 13, 2008

(30) Foreign Application Priority Data
Jun. 15, 2007 (KR) 10-2007-0059162

(51) Int. Cl. G01R 1/073; G01R 31/02; H01R 43/16

(52) U.S. Cl. 324/762; 29/874

(57) ABSTRACT

Disclosed is a probe assembly for use in electrical testing of a testing object and a method of the probe assembly. The probe assembly has a probe supporter body having a first side surface and a first facing surface and a plurality of wire probes. One of the plurality of wire probes has a first arm generally extending in a first direction, a second arm electrically and physically connected to the first arm and generally extending in a second direction other than the first direction, a first terminal portion formed at a distal end of the first arm and comprising a first tip, and a second terminal portion formed at a distal end of the second arm and comprising a second tip. The assembly further has a securing film placed over a portion of the second arm and keeping the portion of the second arm from moving.

### CROSS-REFERENCE TO RELATED PATENT APPLICATIONS

This application claims priority to and the benefit of Korean Patent Application No. 10-2007-0059162, filed Jun. 15, 2007, the disclosure of which is incorporated herein by reference in its entirety.

### BACKGROUND

1. Field

The present disclosure relates to a probe assembly, and more particularly, to a probe assembly with wire probes for use in testing electrical characteristics of a testing object such as a semiconductor device, a flat display or the like.

2. Discussion of the Related Technology

Semiconductor devices are manufactured through a variety of processes including wafer production, wafer test, die packaging and so forth. The wafer test refers to a so-called electrical die sorting test for testing electrical characteristics of the semiconductor devices. In the electrical die sorting test, the semiconductor devices are sorted into acceptable products and unacceptable products by bringing probe pins of a probe card into contact with electrode pads of the semiconductor devices and then allowing an electric current to flow through the electrode pads of the semiconductor devices. In addition to testing the semiconductor devices, the probe card is used in testing data/gate lines in a cell process of flat displays such as a TFT-LCD (Thin Film Transistor-Liquid Crystal Display), a PDP (Plasma Display Panel), an OEL (Organic Electro-Luminescence) and the like.

U.S. Pat. Nos. 7,150,095 and 7,138,812 disclose probe cards in which needle type probes are connected to a printed circuit board. Each of the probe cards disclosed in these patent documents includes a supporter for supporting probes on a printed circuit board. The probes are fixed to the supporter by means of an insulating material and electrically connected to the printed circuit board by soldering.

With the probe cards disclosed in the above patent documents, the probes are aligned using a jig having fine holes that enables a worker to decide the position of the probes. Then, the probes are fixed to the supporters and the printed circuit board by epoxy resin molding and soldering. This sharply reduces productivity of the probe cards and makes it quite difficult to arrange the probes at the same height.

Furthermore, since probes of the probe cards are soldered to the printed circuit board, there is no choice but to replace the probe cards as a whole when one of the probes become defective. This increases the costs involved in maintenance and repair. Moreover, in the probe cards, the probes are coated with an insulating material one by one in order to prevent short-circuit of the probes, which lead to increased production cost and reduced productivity. In the probe cards, the probes are apt to be moved to the left or right in the process of fixing them to the supporter with epoxy resin. This makes it difficult to maintain the pitch between the probes uniform, frequently causing defects in the probe cards.

The foregoing discussion is to provide general background information, and does not constitute an admission of prior art.

### SUMMARY

One aspect of the invention provides a probe assembly for use in electrical testing of a testing object, the probe assembly comprising: a probe supporter body comprising a first side surface and a first facing surface configured to face a testing object; a plurality of wire probes, a first one of the plurality of wire probes comprising: a first arm generally extending along the first side surface in a first direction, a second arm electrically and physically connected to the first arm, the second arm generally extending along the first facing surface in a second direction other than the first direction, a first terminal portion formed at a distal end of the first arm and comprising a first tip configured to contact a testing device, and a second terminal portion formed at a distal end of the second arm and comprising a second tip configured to contact a testing object; and a securing film placed over a portion of the second arm and keeping the portion of the second arm from moving.

In the foregoing assembly, the securing film may comprise a plastic resin material. The securing film may comprise an epoxy material. The securing film may comprise a plurality of layers. The securing film may consist of a single layer. The probe supporter body may comprise an edge where the first side surface and the first facing surface meet, wherein the securing film may comprise an edge generally extend along the edge of the probe supporter body. The portion of the second arm may be interposed between the supporter body and the securing film, wherein the portion of the second arm contacts both the supporter body and the securing film. The first arm and the second arm may have a substantially uniform cross-sectional shape. The cross-sectional shape may be one selected from the group consisting of circle, oval and polygon. The first and second arms may have a substantially uniform thickness along the length thereof.

Still in the foregoing assembly, the second direction may be substantially perpendicular to the first direction. The second direction may be slanted to the first direction with a substantial angle therebetween. The first facing surface may be substantially perpendicular to the first side surface. The first facing surface may be substantially slanted relative to the first side surface. The probe supporter body may further comprise a second side surface and a second facing surface, wherein the second facing surface may be configured to face a testing object.

Yet in the foregoing assembly, The probe supporter body may comprise a recess between the first and second facing surfaces, wherein the recess provides a space into which a portion of the first wire probe can move. A second one of the plurality of probes may comprise: a first arm generally extending along the second side surface in the first direction, a second arm electrically and physically connected to the first arm, the second arm generally extending along the second facing surface in a third direction other than the first direction, wherein the first and second arms have a substantially uniform thickness along the length thereof, a first terminal portion formed at a distal end of the first arm and comprising a first tip configured to contact a testing device, and a second terminal portion formed at a distal end of the second arm and comprising a second tip configured to contact a testing object.

Further in the foregoing assembly, the probe assembly may further comprise an additional securing film placed over the supporter body and a portion of the second arm so as to inhibit the portion of the second arm from moving. The second facing surface may be substantially perpendicular to the second side surface. The first facing surface and the second facing surface may be substantially nonparallel to each other. The probe supporter body may comprise a third facing surface configured to face a testing object and interposed between the first and second facing surface, wherein the third facing surface may be nonparallel to either the first facing surface or the second facing surface. The second facing surface may be substantially slanted relative to the second side surface. The probe assembly may further comprise a plurality of slots formed into the probe supporter body. At least part of the first and second arms may be received in a first one of the plurality of slots.

Another aspect of the invention provides a method of making a probe assembly for use in electrical testing of a testing object, the method comprising: providing a probe supporter body comprising a first side surface and a first facing surface configured to face a testing object; providing a plurality of wire probes, a first one of the plurality of wire probes comprising: a first arm generally extending in a first direction, a second arm connected to the first arm and generally extending in a second direction other than the first direction, a first terminal portion formed at a distal end of the first arm and comprising a first tip, and a second terminal portion formed at a distal end of the second arm and comprising a second tip; arranging the plurality of wire probes such that the first arm generally extends along the first side surface and the second arm generally extends along the first facing surface; placing a securing film over a portion of the second arm; and bonding the supporter body and the securing film so as to keep the portion of the second arm from moving. In the foregoing method, a surface of the securing film comprises an adhesive.

An aspect of the present invention provides a probe assembly for a probe card which are easy to fabricate and can be manufactured with reduced production cost and with greatly increased productivity.

Another aspect of the present invention provides a probe assembly for probe card that can save maintenance and repair cost by making it possible to readily remove probes and supporters from a printed circuit board.

A further aspect of the present invention provides a probe assembly for a probe card that can easily inspect an inspection object having a fine pattern by reducing a pitch between probes mounted to supporters.

In one aspect of the present invention, there is provided a probe assembly for a probe card for transmitting electric signals between an inspection object and a printed circuit board, comprising: a supporter attached to the printed circuit board, the supporter including a first side surface, a first lower surface joined to the first side surface and a plurality of first insertion slots formed across the first side surface and the first lower surface; a plurality of probes inserted into the first insertion slots, each of the probes including a first arm portion inserted into the first insertion slots formed on the first side surface, a second arm portion extending from the first arm portion so that the second arm portion can be inserted into the first insertion slots formed on the first lower surface, a first terminal portion joined to a tip end of the first arm portion so that the first terminal portion can be connected to the printed circuit board and a second terminal portion joined to a tip end of the second arm portion so that the second terminal portion can make contact with the inspection object; and a first insulating resin member attached to the supporter for fixing the probes to the supporter, the first insulating resin member designed to at least partially cover the first insertion slots into which the probes are inserted.

In another aspect of the present invention, there is provided a probe assembly for a probe card for transmitting electric signals between an inspection object and a printed circuit board, comprising: a supporter attached to the printed circuit board, the supporter including a first side surface, a first slanting surface obliquely joined to the first side surface and a plurality of first insertion slots formed across the first side surface and the first slanting surface; a plurality of probes inserted into the first insertion slots, each of the probes including a first arm portion inserted into the first insertion slots formed on the first side surface, a second arm portion extending from the first arm portion so that the second arm portion can be inserted into the first insertion slots formed on the first slanting surface, a first terminal portion joined to a tip end of the first arm portion so that the first terminal portion can be connected to the printed circuit board and a second terminal portion joined to a tip end of the second arm portion so that the second terminal portion can make contact with the inspection object; and a first insulating resin member attached to the supporter for fixing the probes to the supporter, the first insulating resin member designed to at least partially cover the first insertion slots into which the probes are inserted.

### BRIEF DESCRIPTION OF THE DRAWINGS

The above and other aspects and features of the present invention will become apparent from the following description of preferred embodiments, given in conjunction with the accompanying drawings, in which:

FIG. 1 is a perspective view schematically showing a probe assembly for a probe card in accordance with one embodiment of the present invention;

FIG. 2 is a section view schematically illustrating the probe assembly shown in FIG. 1;

FIG. 3 is a front view schematically showing a probe employed in the probe assembly shown in FIG. 1;

FIG. 4 is a perspective view schematically showing a probe assembly for a probe card in accordance with one embodiment of the present invention;

FIG. 5 is a section view schematically illustrating the probe assembly shown in FIG. 4;

FIG. 6 is a front view schematically showing a probe employed in the probe assembly shown in FIG. 4; and

FIG. 7 is a section view illustrating a process of cutting insertion slots in a supporter of the probe assembly shown in FIG. 4.

### DETAILED DESCRIPTION OF EMBODIMENTS

Hereinafter, embodiments of the present invention will be described in detail with reference to the accompanying drawings.

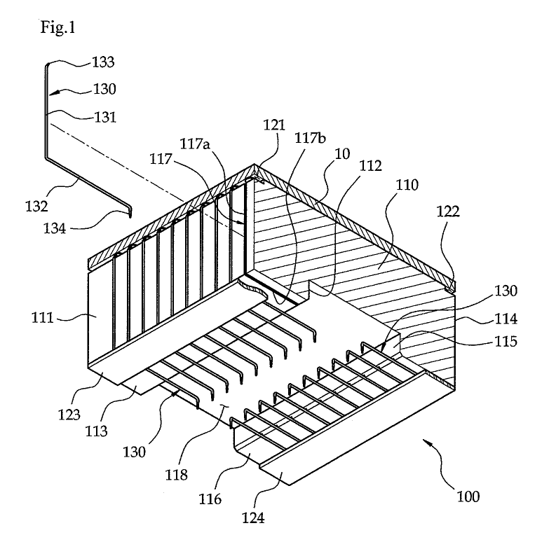

Referring to FIGS. 1 to 3, a probe assembly 100 in accordance with one embodiment of the present invention includes a supporter 110 attached to a lower surface of a printed circuit board 10 with a plurality of electrode pads 15 and a plurality of probes 130 arranged on the opposite side surfaces of the supporter 110 along a longitudinal direction of the latter. The printed circuit board 10 is connected to a test head of a tester (not shown) by means of a pogo block and a performance board unit known in the art.

The supporter 110 is made of an insulating material, e.g., a ceramic material such as zirconia (ZrO₂) or the like. The supporter 110 has first and second side surfaces 111 and 114 extending along the longitudinal direction of the supporter 110 in a parallel relationship with each other. First and second banks 112 and 115 are formed on a lower surface in a spaced-apart relationship with each other, with a central channel or recess 118 left between the first and second banks 112 and 115. The first bank 112 has a first lower surface or first facing surface 113 joined to the first side surface 111 at a right angle. The second bank 115 has a second lower surface or second facing surface 116 joined to the second side surface 114 at a right angle. The angle between the first side surface 111 and the first lower surface 113 and the angle between the second side surface 114 and the second lower surface 116 may be changed to other angles.

The supporter 110 has a plurality of first and second insertion slots 117 and 118. The first insertion slots 117 are formed across the first side surface 111 and the first lower surface 113. Each of the first insertion slots 117 is comprised of a first slot portion 117a formed on the first side surface 111 and a second slot portion 117b formed on the first lower surface 113 of the first bank 112. The second insertion slots 118 are formed across the second side surface 114 and the second lower surface 116. Each of the second insertion slots 118 is comprised of a first slot portion 118a formed on the second side surface 114 and a second slot portion 118b formed on the second lower surface 116. The first and second insertion slots 117 and 118 are arranged on the left and right sides at an equal interval. If needed, the first and second insertion slots 117 and 118 may be arranged at an unequal interval. Each pair of the first and second insertion slots 117 and 118 may be symmetrically arranged on the same transverse plane or may be arranged in a staggering manner.

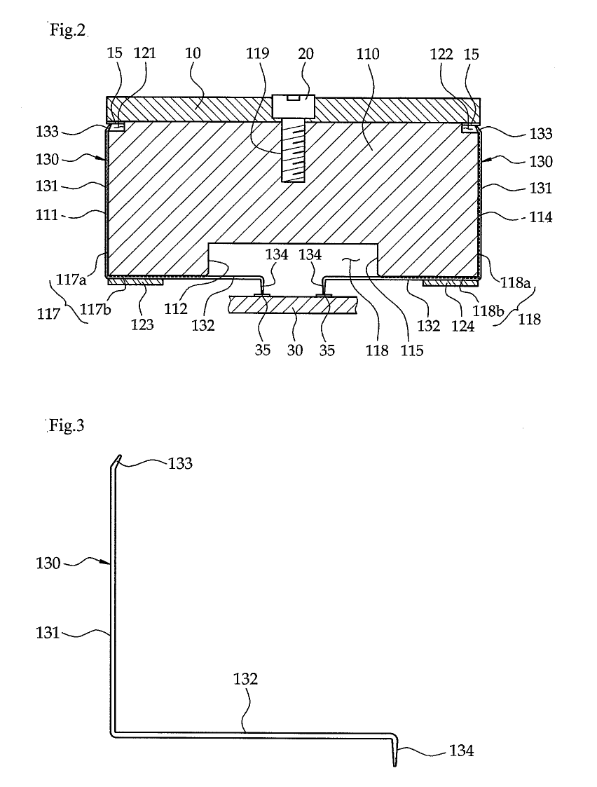

As can be seen in FIGS. 1 and 2, first and second grooves 121 and 122 are formed on the left and right top corners of the supporter 110. The first and second grooves 121 and 122 can be formed by cutting away the left and right top corners of the supporter 110 along the longitudinal direction of the latter. When the supporter 110 is combined with the printed circuit board 10, the electrode pads 15 of the printed circuit board 10 are placed in the first and second grooves 121 and 122. The probes 130 are connected at their first ends to the electrode pads 15 of the printed circuit board 10 in the first and second grooves 121 and 122.

A thread hole 119 is formed on the upper surface of the supporter 110. The supporter 110 is fixed to the lower surface of the printed circuit board 10 by driving a screw 20 into the thread hole 119 of the supporter 110 through the printed circuit board 10. The supporter 110 may be formed into various shapes, including an elongated bar shape and a block shape.

Referring again to FIGS. 1 to 3, the probes 130 are produced by bending a conductive wire into a specified shape. The probes 130 are made of a conductive material such as tungsten, beryllium-copper alloy, beryllium-nickel alloy or the like. The probes 130 thus produced are inserted into the first and second insertion slots 117 and 118 of the supporter 110. The probes 130 serve to transmit electric signals between the printed circuit board 10 and an inspection object 30 such as a wafer, a flat display or the like. The probes 130 are connected at their first ends to the electrode pads 15 of the printed circuit board 10 and make contact with electrode pads 35 of the inspection object 35 at their second ends.

Each of the probes 130 is comprised of first and second arm portions 131 and 132 joined to each other at a right angle, a first terminal portion 133 connected to a corresponding one of the electrode pads 15 of the printed circuit board 10 and a second terminal portion 134 for making contact with a corresponding one of the electrode pads 35 of the inspection object 30. The first terminal portion 133 is formed at a free end of the first arm portion 131 and the second terminal portion 134 is formed at a free end of the second arm portion 132. The first arm portion 131 is inserted into the first slot portion 117a of the first side surface 111 or the first slot portion 118a of the second side surface 114. The second arm portion 132 is at least partially inserted into the second slot portion 117b of the first lower surface 113 or the second slot portion 118b of the second lower surface 116. The angle between the first arm portion 131 and the second arm portion 132 is not limited to the right angle but may be changed depending on the angle between the first side surface 111 and the first lower surface 113 or the angle between the second side surface 114 and the second lower surface 116.

The first terminal portion 133 makes an obtuse angle with the first arm portion 131 and lies outside each of the first insertion slots 117. When the supporter 110 is combined with the printed circuit board 10, the first terminal portion 133 extends into the first groove 121 or the second groove 122 and is connected to the electrode pads 15 of the printed circuit board 10. As the first terminal portion 133 comes into contact with the electrode pads 15, the first terminal portion 133 is elastically deformed and pressed against the electrode pads 15 by an elastic biasing force.

The second terminal portion 134 extends from the free end of the second arm portion 132 at a right angle so that the tip end thereof can face the electrode pads 35 of the inspection object 30. The angle between the second arm portion 132 and the second terminal portion 134 may be changed to other angles than the right angle. When the probes 130 are combined with the supporter 110, the second terminal portion 134 and the end extension of the second arm portion 132 joined to the second terminal portion 134 are positioned in the channel 118. If the second terminal portion 134 is pressed against each of the electrode pads 35 of the inspection object 30, the second arm portion 132 is partially bent to impart an elastic force to the second terminal portion 134. This elastic force allows the second terminal portion 134 to make close contact with the electrode pads 35 of the inspection object 30.

The probes 130 inserted into the first and second insertion slots 117 and 118 are fixed to the supporter 110 by means of first and second insulating resin members or securing film 123 and 124. The first insulating resin member 123 is attached to the first lower surface 113 so that it can partially cover the first insertion slots 117 into which the probes 130 are inserted. Thus, the probes 130 received in the first insertion slots 117 are fixed to the supporter 110 by the first insulating resin member 123. Similarly, the second insulating resin member 124 is attached to the second lower surface 116 so that it can partially cover the second insertion slots 118 into which the probes 130 are inserted. Thus, the probes 130 received in the second insertion slots 118 are fixed to the supporter 110 by the second insulating resin member 124. In this manner, the first and second insulating resin members 123 and 124 serve to fix the probes 130 to the supporter 110, thereby preventing the probes 130 from being removed from the first and second insertion slots 117 and 118. The first and second insulating resin members 123 and 124 may be made of epoxy resin.

In the illustrated embodiment, the first and second insulating resin members 123 and 124 are shown to fix the part of the second arm portion 132 adjoining to the first arm portion 131 to the first and second lower surfaces 113 and 116 so that the second arm portion 132 can be elastically deformed with ease. However, the present invention is not limited thereto and the attachment position of the first and second insulating resin members 123 and 124 may be changed. For example, the first insulating resin member 123 may be attached to different regions of the first side surface 111 or the first lower surface 113 of the supporter 110 so that it can cover at least a part of the first insertion slots 117 into which the probes 130 are inserted. Similarly, the second insulating resin member 124 may be attached to different regions of the second side surface 114 or the second lower surface 116 of the supporter 110 so that it can cover at least a part of the second insertion slots 118 into which the probes 130 are inserted.

Description will now be made on a process of fabricating the probe assembly in accordance with one embodiment of the present invention and an operation thereof.

When fabricating the probe assembly 100, the probes 130 are inserted into the first and second insertion slots 117 and 118 of the supporter 110. At this time, the first arm portion 131 of each of the probes 130 received in the first insertion slots 117 is inserted into the first slot portion 117a formed on the first side surface 111. The second arm portion 132 is partially inserted into second slot portion 117b formed on the first lower surface 113. The first terminal portion 133 is positioned in the first groove 121. The second terminal portion 134 and the end extension of the second arm portion 132 joined to the second terminal portion 134 are positioned in the channel 118. Similarly, the first arm portion 131 of each of the probes 130 received in the second insertion slots 118 is inserted into the first slot portion 118a formed on the second side surface 114. The second arm portion 132 is partially inserted into second slot portion 118b formed on the second lower surface 116. The first terminal portion 133 is positioned in the second groove 122. The second terminal portion 134 and the end extension of the second arm portion 132 joined to the second terminal portion 134 are positioned in the channel 118.

Once the probes 130 are inserted into the first and second insertion slots 117 and 118, the first and second insulating resin members 123 and 124 are applied to the first and second banks 112 and 115 of the supporter 110 to partially cover the second arm portion 132 of each of the probes 130. If the first and second insulating resin members 123 and 124 are fully cured, the probes 130 are firmly fixed to the supporter 110 by the bonding force of the insulating resin members 123 and 124. Thus, the process of fabricating the probe assembly 100 comes to an end.

As described above, the probe assembly 100 in accordance with one embodiment of the present invention is of the type wherein the probes 130 are inserted into the first and second insertion slots 117 and 118 formed in the supporter 110. This makes it possible to fix the probes 130 in a specified position with no possibility that the probes 130 are out of alignment in the fabricating process. Therefore, it is possible to accurately and easily align and fix the probes 130 to the supporter 110 without having to use a jig. Furthermore, since the first arm portion 131 of each of the probes 130 is inserted into the first slot portion 117a and 118a with the second arm portion 132 inserted into the second slot portion 117b and 118b, the probes 130 fitted to the supporter 110 are seldom deformed by an external force.

The probe assembly 100 thus fabricated is attached to the lower surface of the printed circuit board 10 by means of the screw 20. As can be seen in FIG. 2, if the screw 20 is driven into the thread hole 119 of the supporter 110 through the printed circuit board 10, the upper surface of the supporter 110 is brought into close contact with the lower surface of the printed circuit board 10 and the first terminal portion 133 of each of the probes 130 are connected to the corresponding one of the electrode pads 15 of the printed circuit board 10. In this process, the first terminal portion 133 is elastically deformed and is pressed against the corresponding one of the electrode pads 15. Therefore, the probes 130 are stably connected to the printed circuit board 10 with no soldering.

Although not shown in the drawings, a space transformer and an interposer for transmitting an electric signal may be positioned between the probe assembly 100 and the printed circuit board 10. In this case, the probes 130 are brought into contact with electrode pads of the space transformer.

The probe assembly 100 thus fabricated is used in producing a probe card. The probe card is connected to a test head (not shown). When performing a test of the inspection object 30, the test head is operated to bring the second terminal portions 134 of the probes 130 into contact with the electrode pads 35 of the inspection object 30 as shown in FIG. 2. As the second terminal portions 134 of the probes 130 come into contact with the electrode pads 35, the second arm portions 132 are elastically deformed by the force applied to the second terminal portions 134. At this time, the second arm portions 132 resiliently press the second terminal portions 134 into close contact with the electrode pads 35. This prevents the second terminal portions 134 from making incomplete contact with the electrode pads 35, which in turn greatly increases the reliability and repeatability of the test for the inspection object 30.

With the probe assembly 100 in accordance with one embodiment of the present invention, if the probes 130 are damaged in the fabricating process or during the process of testing the inspection object 30, the probe assembly 100 can be easily replaced with a new one by removing the supporter 110 having the damaged probes 130 from the printed circuit board 10. This makes it easy to perform the tasks of maintenance and repair and helps to reduce the costs involved in maintenance and repair.

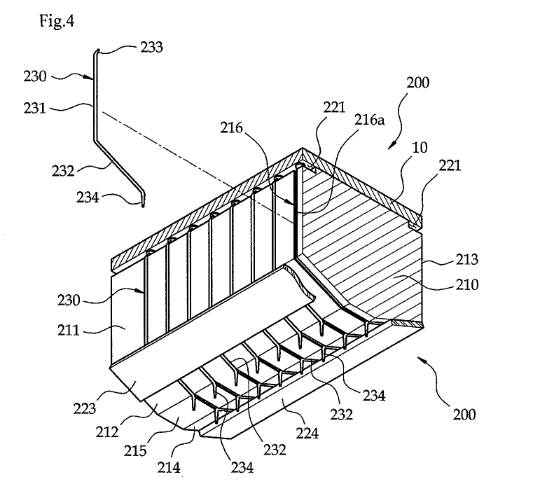

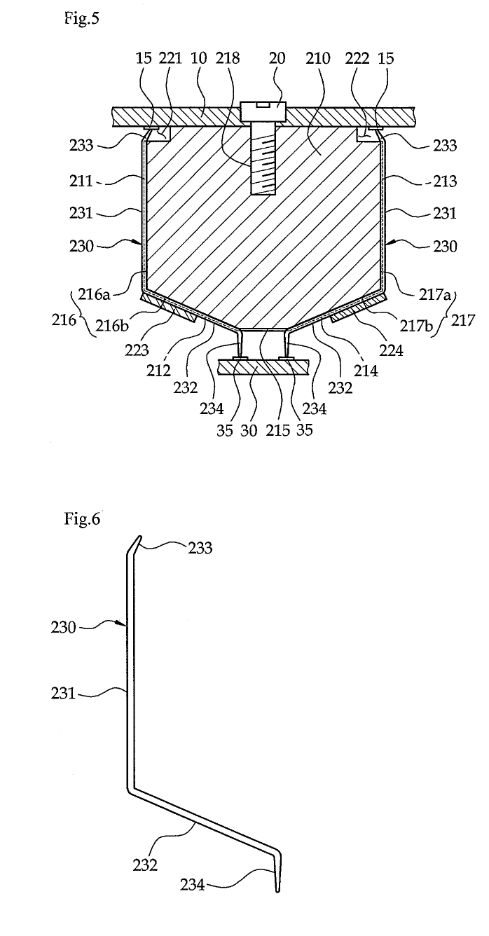

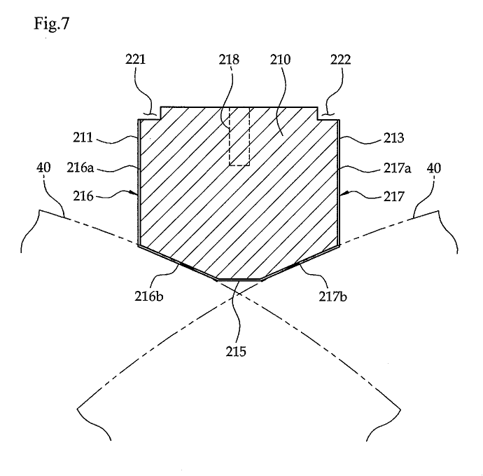

FIGS. 4 to 7 show a probe assembly in accordance with one embodiment of the present invention. As shown in FIGS. 4 and 5, the probe assembly 200 in accordance with one embodiment of the present invention includes a supporter 210 attached to the lower surface of the printed circuit board 10 with electrode pads 15 and a plurality of wire-type probes 230 fixed to the opposite side surfaces of the supporter 210 along the longitudinal direction of the latter.

The supporter 210 has first and second side surfaces 211 and 213 extending along the longitudinal direction of the supporter 210 in a parallel relationship with each other, a first slanting surface or first facing surface 212 joined to the first side surface 211, a second slanting surface or second facing surface 214 joined to the second side surface 213, a lower surface or third facing surface 215 interconnecting the first slanting surface 212 and the second slanting surface 214, and a plurality of first and second insertion slots 216 and 217. The first insertion slots 216 are formed on the left side of the supporter 210 in the drawings to extend in the vertical and transverse directions of the supporter 210. The second insertion slots 217 are formed on the right side of the supporter 210 in the drawings to extend in the vertical and transverse directions of the supporter 210. The first and second insertion slots 216 and 217 are arranged in a spaced-apart relationship along the longitudinal direction of the supporter 210.

Each of the first insertion slots 216 is comprised of a first slot portion 216a formed on the first side surface 211 and a second slot portion 216b formed on the first slating surface 212. Similarly, each of the second insertion slots 217 is comprised of a first slot portion 217a formed on the second side surface 213 and a second slot portion 217b formed on the second slating surface 214. The first and second insertion slots 216 and 217 may be formed on the lower surface 215.

First and second grooves 221 and 222 are formed on the left and right top corners of the supporter 210 along the longitudinal direction of the latter. A thread hole 218 is formed on the upper surface of the supporter 210. When combining the supporter 210 with the printed circuit board 10, a screw 20 is driven into the thread hole 218 through the thickness of the printed circuit board 10, in which state the electrode pads 15 of the printed circuit board 10 are exposed to the first and second grooves 221 and 222.

As can be seen in FIGS. 4 to 6, the wire-type probes 230 are fitted to the first and second insertion slots 216 and 217 of the supporter 210. The probes 230 may be produced by bending a conductive wire. Each of the probes 230 is comprised of a first arm portion 231, a second arm portion 232, a first terminal portion 233 and a second terminal portion 234. The first arm portion 231 is formed into a length corresponding to the height of the first side surface 211. The second arm portion 232 extends obliquely downwardly from the first arm portion 231. The first terminal portion 233 extends obliquely upwardly from the first arm portion 231 and the second terminal portion 234 extends vertically downwardly from the second arm portion 232.

When fitting the probes 230 to the first insertion slots 216 of the supporter 210, the first arm portion 231 of each of the probes 230 is inserted into the first slot portion 216a of the first side surface 211 and the second arm portion 232 is inserted into the second slot portion 216b of the first slanting surface 212. The first terminal portion 233 extends into the first groove 221 and the second terminal portion 234 protrudes downwardly from the supporter 210. In the same manner, the probes 230 are also fitted to the second insertion slots 217 of the supporter 210. The probes 230 fitted to the first and second insertion slots 216 and 217 are fixed to the supporter 210 by means of first and second insulating resin members 223 and 224.

The first insulating resin member 223 is attached to the first slanting surface 212 to partially cover the first insertion slots 216 into which the second arm portions 232 of the probes 230 are inserted. The second insulating resin member 224 is attached to the second slanting surface 214 to partially cover the second insertion slots 217 into which the second arm portions 232 of the probes 230 are inserted.

In the present embodiment, the first insulating resin member 223 may be attached to different regions of the first side surface 211 or the first slanting surface 212 of the supporter 210 so that it can cover at least a part of the first insertion slots 216 into which the probes 230 are inserted. Similarly, the second insulating resin member 224 may be attached to different regions of the second side surface 213 or the second slanting surface 214 of the supporter 210 so that it can cover at least a part of the second insertion slots 217 into which the probes 130 are inserted.

With the probe assembly 200 of the present embodiment set forth above, the probes 230 are inserted into the first and second insertion slots 216 and 217 of the supporter 210. This makes it possible to accurately and easily fit the probes 230 to the supporter 210. Furthermore, since the probes 230 are inserted into and supported by the first and second insertion slots 216 and 217, it becomes possible to avoid deformation of the probes 230 and also to assure a prolonged lifespan thereof.

The probe assembly 200 of the present embodiment is attached to the lower surface of the printed circuit board 10 by means of the screw 20. In other words, the probe assembly 200 is firmly secured to the printed circuit board 10 by driving the screw 20 into the thread hole 218 of the supporter 210 through the thickness of the printed circuit board 10. At this time, the first terminal portions 233 of the probes 230 are connected to the electrode pads 15 of the printed circuit board 10 in the first and second grooves 221 and 222. When making contact with the electrode pads 15, the first terminal portions 233 are elastically deformed and pressed against the electrode pads 15 by a resilient force.

When performing a test of the inspection object 30, the second terminal portions 234 of the probes 230 are brought into contact with the electrode pads 35 of the inspection object 30 as shown in FIG. 5. As the second terminal portions 234 of the probes 230 come into contact with the electrode pads 35, they are elastically deformed and resiliently pressed against the electrode pads 35. This increases the reliability and repeatability of the test for the inspection object 30.

FIG. 7 illustrates a process of cutting the insertion slots in the supporter of the probe assembly shown in FIG. 4. The first and second insertion slots 216 and 217 are cut on the opposite side surfaces of the supporter 210 by a wheel cutter 40 having a specified diameter, e.g., a diameter of 55.4 mm. In the process of cutting the first and second insertion slots 216 and 217, the first insertion slots 216 are first cut on the first side surface 211 and the first slanting surface 212 by means of the wheel cutter 40. Then, the second insertion slots 217 are cut on the second side surface 213 and the second slanting surface 214. The first insertion slots 216 may be formed on the lower surface 215 when cutting the first insertion slots 216 on the first slanting surface 212. Similarly, the second insertion slots 217 may be formed on the lower surface 215 when cutting the second insertion slots 217 on the second slanting surface 214.

Therefore, the first and second insertion slots 216 and 217 may be overlapped in the lower surface 215 either in case they are formed at an equal interval on the same cross-sectional plane or in case they are formed at an unequal interval on different cross-sectional planes. If the supporter 210 is reduced in width or if the probes 230 are arranged in a smaller pitch to inspect an inspection object of high density, the overlapping amount of the first and second insertion slots 216 and 217 in the lower surface 215 becomes greater.

Even though the first and second insertion slots 216 and 217 are overlapped in the lower surface 215, no overlapping occurs in the first slanting surface 212 and the second slanting surface 214. Therefore, the second arm portions 232 of the probes 230 are inserted into and immovably fixed to the second slot portions 216b and 217b of the first slanting surface 212 and the second slanting surface 214. The second terminal portions 234 of the probes 230 make contact with the electrode pads 35 of the inspection object 30 with increased accuracy, which in turn increases the reliability and repeatability of the test for the inspection object 30.

As described hereinabove, the probe assembly for a probe card is of the structure wherein the probes are inserted into the insertion slots of the insulating supporter. This makes it possible to fabricate the probe assembly in an easy and accurate manner and with greatly increased productivity. Furthermore, the probes are allowed to make accurate mechanical contact with the electrode pads of the printed circuit board and are restrained from unnecessary movement, thereby sharply increasing the reliability of a product. Moreover, the probe assembly having a defective probe can be removed from the printed circuit board on a one-by-one basis. This makes it easy to replace components and to reduce the costs involved in maintenance and repair. In addition, it is possible to reduce the pitch between the probes while preventing occurrence of a short circuit of the probes. This makes it possible to cope with the increase in density of the inspection object.

The present invention is not limited to embodiments shown and described hereinabove. It will be understood by those skilled in the art that various changes and modifications may be made without departing from the scope of the invention defined in the claims.

What is claimed is:

1. A probe assembly for use in electrical testing of a testing object, the probe assembly comprising:
a probe supporter body comprising a first side surface and a first facing surface configured to face a testing object;
a plurality of wire probes, a first one of the plurality of wire probes comprising:
a first arm generally extending along the first side surface in a first direction,
a second arm electrically and physically connected to the first arm, the second arm generally extending along the first facing surface in a second direction other than the first direction,
a first terminal portion formed at a distal end of the first arm and comprising a first tip configured to contact a testing device, and
a second terminal portion formed at a distal end of the second arm and comprising a second tip configured to contact a testing object; and
a securing film placed over a portion of the second arm and keeping the portion of the second arm from moving, wherein the portion of the second arm is interposed between the probe supporter body and the securing film, wherein the portion of the second arm contacts both the probe supporter body and the securing film.

2. The probe assembly of claim 1, wherein the securing film comprises a plastic resin material.

3. The probe assembly of claim 1, wherein the securing film comprises an epoxy material.

4. The probe assembly of claim 1, wherein the securing film comprises a plurality of layers.

5. The probe assembly of claim 1, wherein the securing film consists of a single layer.

6. The probe assembly of claim 1, wherein the probe supporter body comprises an edge where the first side surface and the first facing surface meet, wherein the securing film comprises an edge generally extend along the edge of the probe supporter body.

7. The probe assembly of claim 1, wherein the first arm and the second arm have a substantially uniform cross-sectional shape.

8. The probe assembly of claim 7, wherein the cross-sectional shape is one selected from the group consisting of circle, oval and polygon.

9. The probe assembly of claim 1, wherein the first and second arms have a substantially uniform thickness along the length thereof.

10. The probe assembly of claim 1, wherein the second direction is substantially perpendicular to the first direction.

11. The probe assembly of claim 1, wherein the second direction is slanted to the first direction with a substantial angle therebetween.

12. The probe assembly of claim 1, wherein the first facing surface is substantially perpendicular to the first side surface.

13. The probe assembly of claim 1, wherein the first facing surface is substantially slanted relative to the first side surface.

14. The probe assembly of claim 1, wherein the probe supporter body further comprises a second side surface and a second facing surface, wherein the second facing surface is configured to face a testing object.

15. The probe assembly of claim 14, wherein the probe supporter body comprises a recess between the first and second facing surfaces, wherein the recess provides a space into which a portion of the first wire probe can move.

16. The probe assembly of claim 14, wherein a second one of the plurality of probes comprises:
a first arm generally extending along the second side surface in the first direction,
a second arm electrically and physically connected to the first arm, the second arm generally extending along the second facing surface in a third direction other than the first direction, wherein the first and second arms have a substantially uniform thickness along the length thereof,
a first terminal portion formed at a distal end of the first arm and comprising a first tip configured to contact a testing device, and
a second terminal portion formed at a distal end of the second arm and comprising a second tip configured to contact a testing object.

17. The probe assembly of claim 16, further comprises an additional securing film placed over the second arm of the second wire probe and the second facing surface and a portion of the second arm of the second wire probe so as to inhibit the portion of the second arm of the second wire probe from moving, wherein the portion of the second arm of the second wire probe is interposed between the probe supporter body and the additional securing film.

18. The probe assembly of claim 14, wherein the second facing surface is substantially perpendicular to the second side surface.

19. The probe assembly of claim 14, wherein the first facing surface and the second facing surface are substantially nonparallel to each other.

20. The probe assembly of claim 14, wherein the probe supporter body comprises a third facing surface configured to face a testing object and interposed between the first and second facing surface, wherein the third facing surface is nonparallel to either the first facing surface or the second facing surface.

21. The probe assembly of claim 14, wherein the second facing surface is substantially slanted relative to the second side surface.

22. The probe assembly of claim 1, further comprising a plurality of slots formed into the probe supporter body.

23. The probe assembly of claim 22, wherein at least part of the first and second arms is received in a first one of the plurality of slots.

24. A method of making a probe assembly for use in electrical testing of a testing object, the method comprising:
providing a probe supporter body comprising a first side surface and a first facing surface configured to face a testing object;
providing a plurality of wire probes, a first one of the plurality of wire probes comprising:
a first arm generally extending in a first direction,
a second arm connected to the first arm and generally extending in a second direction other than the first direction,
a first terminal portion formed at a distal end of the first arm and comprising a first tip, and
a second terminal portion formed at a distal end of the second arm and comprising a second tip;
arranging the plurality of wire probes such that the first arm generally extends along the first side surface and the second arm generally extends along the first facing surface;
placing a securing film over a portion of the second arm; and
bonding the probe supporter body and the securing film so as to keep the portion of the second arm from moving.

25. The method of claim 24, wherein a surface of the securing film comprises an adhesive.
